(19) United States
(12) Patent Application Publication
(10) Pub. No.: US 2025/0024740 A1
(43) Pub. Date: Jan. 16, 2025

(54) DISPLAY DEVICE

(71) Applicant: Samsung Display Co., LTD., Yongin-si (KR)

(72) Inventor: HYUNGJUNE KIM, Yongin-si (KR)

(21) Appl. No.: 18/631,761

(22) Filed: Apr. 10, 2024

(30) Foreign Application Priority Data
Jul. 10, 2023 (KR) 10-2023-0089291

(51) Int. Cl. H10K 59/80; H10K 59/35

(52) U.S. Cl. CPC H10K 59/879; H10K 59/35

(57) ABSTRACT

A display device includes a first base layer including a first display area including a first pixel area and a second display area at least partially surrounded by the first display area and including a transmission area and a second pixel area, a first barrier layer disposed on the first base layer and including a first inorganic layer having a first thickness and a second inorganic layer having a second thickness thinner than the first thickness, a second base layer disposed on the first barrier layer, a second barrier layer disposed on the second base layer and including a third inorganic layer having a third thickness and a fourth inorganic layer having a fourth thickness thinner than the third thickness, and a plurality of pixel disposed in the first and second pixel areas on the second barrier layer.

This application claims priority to Korean Patent Application No. 10-2023-0089291, filed on Jul. 10, 2023, and all the benefits accruing therefrom under 35 U.S.C. § 119, the content of which in its entirety is herein incorporated by reference.

### BACKGROUND

### 1. Technical Field

The invention relates to a display device and more particularly, to a display device that provides information.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Meanwhile, various functional modules that can be used with the display device are being added to the display device. For example, a user may take photos, videos, and the like using a camera module disposed inside the display device.

### SUMMARY

In an embodiment, a display device is provided that improves a quality of image displayed through a functional module (e.g., a camera module).

A display device, according to embodiments, includes a first base layer including a first display area including a first pixel area and a second display area at least partially surrounded by the first display area and including a transmission area and a second pixel area, a first barrier layer disposed on the first base layer and including a first inorganic layer having a first thickness and a second inorganic layer having a second thickness thinner than the first thickness, a second base layer disposed on the first barrier layer, a second barrier layer disposed on the second base layer and including a third inorganic layer having a third thickness and a fourth inorganic layer having a fourth thickness thinner than the third thickness, and a plurality of pixels disposed in the first and second pixel areas on the second barrier layer. Each of the first and third thicknesses satisfies Equation 1 below and each of the second and fourth thicknesses satisfies Equation 2 below:

$$T 1 = ( {λ}_{1} xm / 2 ) / {n}_{1} , \qquad [ Equation 1 ]$$

$$T 2 = ( {λ}_{2} xm / 2 ) / {n}_{2} , \qquad [ Equation 2 ]$$

Where, in Equation 1, T1 is thickness (Å) of any one of the first and third thicknesses, λ1 is a first wavelength within a visible light wavelength range, and n₁ is a refractive index of any one of the first and third inorganic layers. In Equation 2, T2 is thickness (Å) of any one of the second and fourth thicknesses, λ2 is a second wavelength within a visible light wavelength range, and n₂ is a refractive index of any one of the second and fourth inorganic layers. In Equation 1 and Equation 2, m is a natural number.

In an embodiment, the first thickness may be substantially the same as the third thickness, and the second thickness may be substantially a same as the fourth thickness.

In an embodiment, the first wavelength may be a wavelength of green light and the second wavelength may be a wavelength of blue light.

In an embodiment, each of the first thickness, second thickness, third thickness, and fourth thickness may range from about 1000 Å to about 10000 Å.

In an embodiment, a refractive index of the first base layer may be greater than a refractive index of the first inorganic layer, and the refractive index of the first inorganic layer may be greater than a refractive index of the second inorganic layer.

In an embodiment, a refractive index of the second base layer may be greater than a refractive index of the third inorganic layer, and the refractive index of the third inorganic layer may be greater than a refractive index of the fourth inorganic layer.

In an embodiment, the first and third inorganic layers may include silicon oxynitride, and the second and fourth inorganic layers may include silicon oxide.

In an embodiment, the display device may further include a buffer layer disposed on the second base layer and including an inorganic material.

In an embodiment, a refractive index of the buffer layer may be greater than the refractive index of each of the first inorganic layer, second inorganic layer, third inorganic layer, and fourth inorganic layer.

In an embodiment, each of the first base layer and the second base layer may include polyimide.

In an embodiment, each of the first base layer and the second base layer may include silicon nitride.

In an embodiment, a transmittance of the first display area may be smaller than a transmittance of the second display area.

In an embodiment, the display device may further include a functional module disposed under the first base layer corresponding to the second display area.

In an embodiment, the functional module may include at least one of a camera module, a face recognition sensor module, a pupil recognition sensor module, an acceleration sensor module, a proximity sensor module, an infrared senser module, and an illuminance sensor module.

A display device, according to an embodiment, includes a first base layer including a first display area including a first pixel area and a second display area at least partially surrounded by the first display area and including a transmission area and a second pixel area, a first barrier layer disposed on the first base layer and including a first inorganic layer having a first thickness and a second inorganic layer having a second thickness thinner than the first thickness, a second base layer disposed on the first barrier layer, a second barrier layer disposed on the second base layer and including a third inorganic layer having a third thickness and a fourth inorganic layer having a fourth thickness thinner than the third thickness, and a plurality of pixels disposed in the first and second pixel areas on the second barrier layer. The first thickness is determined by dividing a first wavelength of green light by a refractive index of the first inorganic layer, and the second thickness is determined by dividing a second wavelength of blue light by a refractive index of the second inorganic layer.

In an embodiment, the first thickness may range from about 2900 Å to about 3600 Å, and the second thickness may range from about 2700 Å to about 3400 Å.

In an embodiment, a refractive index of the first base layer may be greater than a refractive index of the first inorganic layer, and the refractive index of the first inorganic layer may be greater than a refractive index of the second inorganic layer.

In an embodiment, a refractive index of the second base layer may be greater than a refractive index of the third inorganic layer, and the refractive index of the third inorganic layer may be greater than a refractive index of the fourth inorganic layer.

In an embodiment, the first and third inorganic layers may include silicon oxynitride, and the second and fourth inorganic layers may include silicon oxide.

In an embodiment, the display device may further include a buffer layer disposed on the second base layer and including an inorganic material.

In an embodiment, a refractive index of the buffer layer may be greater than the refractive index of each of the first inorganic layer, second inorganic layer, third inorganic layer, and fourth inorganic layer.

In an embodiment, each of the first base layer and the second base layer may include polyimide.

In an embodiment, each of the first base layer and the second base layer may include silicon nitride.

In a display device, according to an embodiment, a substrate may include a first base layer having a relatively high refractive index, a first barrier layer including an inorganic material, and a second base layer having a relatively high refractive index, and a second barrier layer including an inorganic material may be disposed on the second base layer. Each of the first barrier layer and the second barrier layer may include a first inorganic layer having a relatively medium refractive index and a second inorganic layer having a relatively small refractive index. A thickness of the first inorganic layer may be determined by the wavelength of the green light, a multiple of ½, and a refractive index of the first inorganic layer. A thickness of the second inorganic layer may be determined by the wavelength of the blue light, a multiple of ½, and a refractive index of the second inorganic layer.

Accordingly, an average transmittance of a transmission area for blue light divided by an average transmittance of the transmission area for green light can be relatively increased. In this case, the yellowish color of the image displayed through a functional module (e.g., camera module) disposed in the transmission area can be minimized or reduced.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device, according to an embodiment.

FIG. 2 is a cross-sectional view schematically illustrating a first display area and a second display area of the display device of FIG. 1, according to an embodiment.

FIG. 3 is a plan view illustrating a part of the first display area of the display device of FIG. 1, according to an embodiment.

FIG. 4 is a plan view illustrating a part of the second display area of the display device of FIG. 1, according to an embodiment.

FIG. 5 is a plan view illustrating an example of area A of FIG. 4, according to an embodiment.

FIG. 6 is a plan view illustrating another example of area A of FIG. 4, according to an embodiment.

FIG. 7 is a cross-sectional view of part of the first display area taken along line I-I′ of FIG. 3, according to an embodiment.

FIG. 8 is a cross-sectional view of part of the second display area taken along line II-II′ of FIG. 4, according to an embodiment.

FIG. 9 is a cross-sectional view illustrating a substrate and a second barrier layer of FIGS. 7 and 8, according to an embodiment.

FIG. 10 is a graph illustrating a transmittance of the barrier layer for the wavelength of visible light, according to an embodiment.

FIG. 11 is a graph illustrating a transmittance of the barrier layer for the wavelength of visible light, according to an embodiment.

FIG. 12 is a graph illustrating a transmittance of a transmission area for a first wavelength included in a visible light wavelength range, according to an embodiment.

FIG. 13 is a graph illustrating a transmittance of a transmission area for a first wavelength included in a visible light wavelength range, according to an embodiment.

### DETAILED DESCRIPTION OF THE EMBODIMENTS

Hereinafter, a display device according to embodiments of the invention will be explained in detail with reference to the accompanying drawings. The same reference numerals are used for the same components in the drawings, and redundant descriptions of the same components will be omitted.

The invention will now be described more fully hereinafter with reference to the accompanying drawings, in which various embodiments are shown. The invention may, however, be embodied in many different forms, and should not be construed as limited to the embodiments set forth herein. Rather, these embodiments are provided so that this disclosure will be thorough and complete, and will fully convey the scope of the invention to those skilled in the art.

While describing each drawing, similar reference numerals are used for similar components. In the attached drawings, the dimensions of the structures are enlarged from the actual size for clarity of the present disclosure.

In this application, terms such as “include (or comprise)” or “have” are intended to designate the presence of features, numbers, steps, operations, components, parts, or combinations thereof described in the specification, it should be understood that this does not exclude in advance the presence or addition of elements, numbers, steps, operations, components, parts, or combinations thereof.

In this application, when a part of a layer, membrane, area, region, plate, or the like is said to be “on (or above)” or “on the top” another part, this includes not only cases where it is “directly on” the other part, but also cases where there is another part in between. Conversely, when a part of a layer, membrane, area, region, plate, or the like is said to be “under (or below)” or “at the bottom” another part, this includes not only being “directly under” another part, but also cases where there is another part in between. In addition, in this application, being disposed “on” may include being disposed not only at the top but also at the bottom.

In this application, “directly disposed” may mean that there is no additional layer, film, area, region, plate, or the like between a part of the layer, film, area, region, plate, or the like and another part. For example, “directly disposed” may mean disposed without using an additional member, such as an adhesive member, between two layers or two members. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

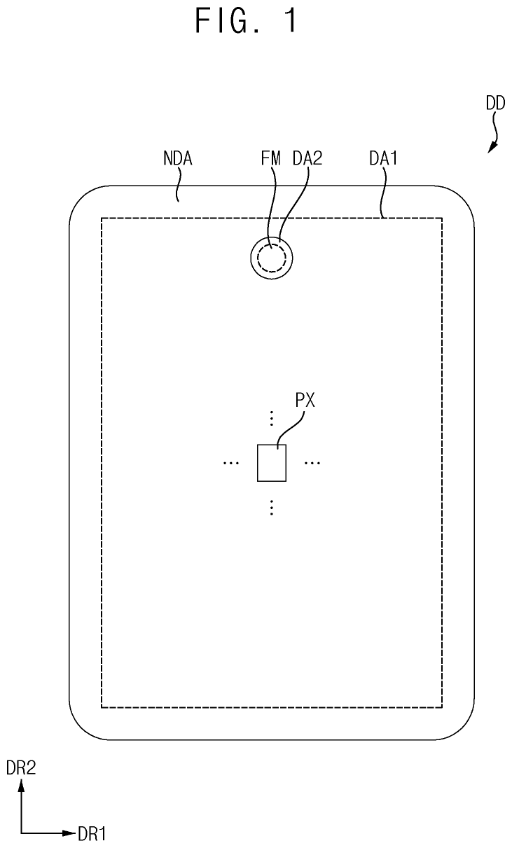

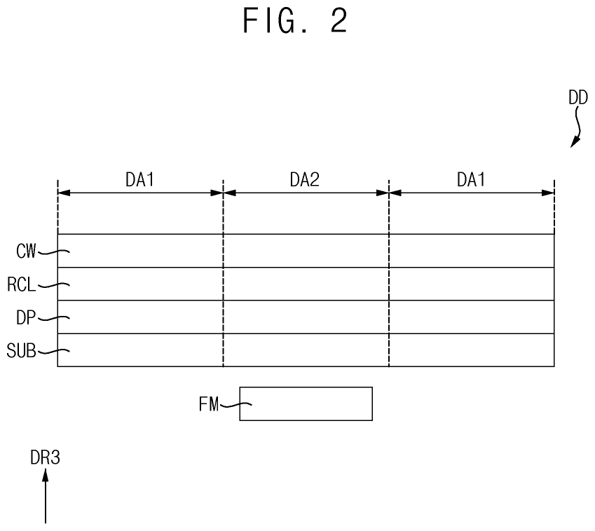

FIG. 1 is a plan view illustrating a display device, according to an embodiment. FIG. 2 is a cross-sectional view schematically illustrating a first display area and a second display area of the display device of FIG. 1, according to an embodiment.

Referring to FIGS. 1 and 2, a display device DD, according to an embodiment, may include a substrate SUB, a display portion DP, an anti-reflection layer RCL, and a cover window CW.

In an embodiment, the display device DD may include a first display area DA1, a second display area DA2, and a non-display area NDA. Each of the first display area DA1 and the second display area DA2 may display an image. The non-display area NDA might not display an image. The non-display area NDA may be positioned around the first display area DA1. For example, the non-display area NDA may surround at least a part of the first display area DA1.

In an embodiment, a plurality of pixels PX may be disposed in each of the first display area DA1 and the second display area DA2. The plurality of pixels PX may be disposed in a matrix form along a first direction DR1 and a second direction DR2 crossing the first direction DR1. Each of the plurality of pixels PX may include a transistor and a light emitting element electrically connected to the transistor. Accordingly, each of the plurality of pixels PX may emit light of a specific color (e.g., red, green, blue, and the like).

In an embodiment, the second display area DA2 may include a transmission area through which external light is transmitted. As the second display area DA2 includes the transmission area through which external light is transmitted, the transmittance of the second display area DA2 may be greater than that of the first display area DA1. That is, the transmittance of the first display area DA1 may be smaller than the transmittance of the second display area DA2. In other words, the second display area DA2 may transmit external light incident on the second display area DA2 while displaying an image.

In an embodiment, the first display area DA1 and the second display area DA2 may be located adjacent to each other. In an embodiment, the first display area DA1 may surround at least a part of the second display area DA2. For example, the second display area DA2 may be positioned within the display device DD and spaced apart from an edge of the display device DD in a plan view, and the first display area DA1 may surround an entire second display area DA2.

In an embodiment, the second display area DA2 may have a smaller density of pixels PX than the first display area DA1. That is, the second display area DA2 may have a smaller number of pixels PX per unit area than the first display area DA1.

In an embodiment, the second display area DA2 may have a circular planar shape. However, embodiments are not limited to this, and the second display area DA2 may have various polygonal planar shapes.

In an embodiment, a plurality of drivers may be disposed in the non-display area NDA. For example, the drivers may include a gate driver, an emission control driver, a data driver, and the like. The drivers may provide a gate signal, a data signal, an emission control signal, and the like to the pixels PX.

In an embodiment, the display portion DP may be disposed on the substrate SUB. The display portion DP may overlap the first display area DA1 and the second display area DA2. The display portion DP may include the plurality of pixels PX to display an image. A detailed description of the display portion DP will be described later.

In an embodiment, the functional module FM may be disposed under the substrate SUB corresponding to the second display area DA2. The functional module FM may receive external light passing through the second display area DA2. In an embodiment, the functional module FM may include a camera module for capturing (or recognizing) an image of an object positioned in front of the display device DD, a facial recognition sensor module to detect the user's face, a pupil recognition sensor module to detect the user's pupils, an acceleration sensor module and a geomagnetic sensor module to determine the movement of the display device DD, a proximity sensor module and an infrared sensor module for detecting the proximity of the front of the display device DD, an illuminance sensor module to measure the level of external brightness, and/or the like.

In an embodiment, the anti-reflection layer RCL may be disposed on the display portion DP. The anti-reflection layer RCL may overlap the first display area DA1 and the second display area DA2. External light reflection can be reduced through the anti-reflection layer RCL. For example, the anti-reflection layer RCL may include a polarizing layer and a phase delay layer. Alternatively, the anti-reflection layer RCL may include a black matrix and a color filter.

In an embodiment, the cover window CW may be disposed on the anti-reflection layer RCL. The cover window CW may overlap the first display area DA1 and the second display area DA2. The cover window CW may be disposed on the display portion DP to protect the display portion DP. The cover window CW may include a transparent material. For example, the cover window CW may include a glass substrate or a polymer substrate.

In this specification, a plane may be defined as the first direction DR1 and the second direction DR2 that intersects the first direction DR1. For example, the first direction DR 1 and the second direction DR2 may be perpendicular to each other. In addition, a third direction DR3 may be perpendicular to the plane.

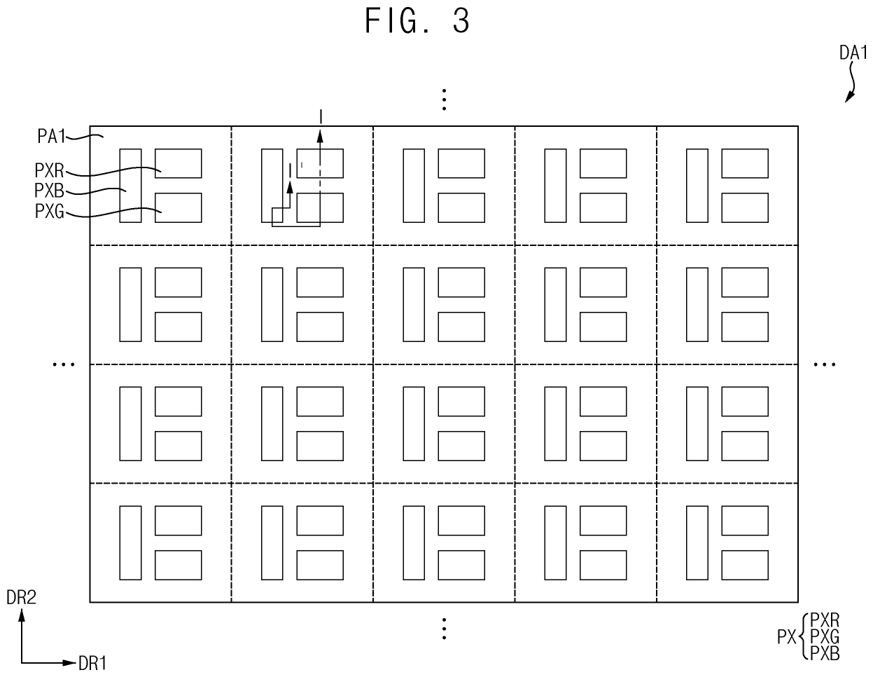

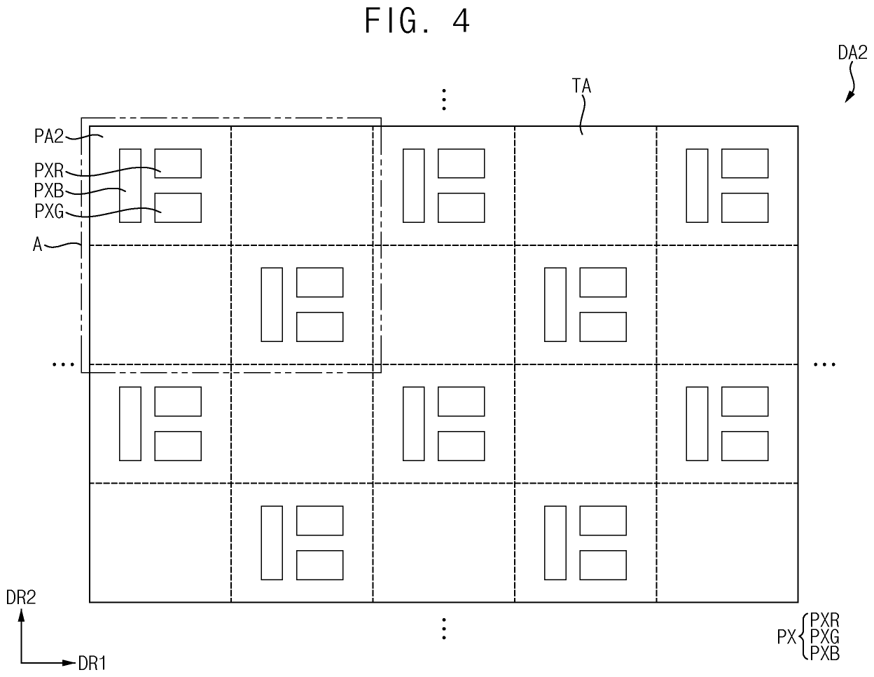

FIG. 3 is a plan view illustrating a part of the first display area of the display device of FIG. 1, according to an embodiment. FIG. 4 is a plan view illustrating a part of the second display area of the display device of FIG. 1, according to an embodiment.

In an embodiment and referring to FIGS. 2, 3, and 4, the first display area DA1 may include a plurality of first pixel areas PA1, and the second display area DA2 may include a plurality of second pixel areas PA2 and a plurality of transmission areas TA. The transmission areas TA may be positioned between the second pixel areas PA2.

In an embodiment, the plurality of pixels PX may be disposed in the first pixel areas PA1. In addition, a plurality of pixels PX may be disposed in the second pixel areas PA2. Specifically, one pixel may be disposed in each of the first pixel areas PA1 and one pixel may be disposed in each of the second pixel areas PA2.

In an embodiment, each of the plurality of pixels PX may include a plurality of sub-pixels that emit light of different colors. For example, each of the plurality of pixels PX may include a red sub-pixel PXR that emits red light, a green sub-pixel PXG that emits green light, and a blue sub-pixel PXB that emits blue light.

For example, in an embodiment, one red sub-pixel PXR, one green sub-pixel PXG, and one blue sub-pixel PXB may be disposed in each of the first pixel areas PA1. In addition, one red sub-pixel PXR, one green sub-pixel PXG, and one blue sub-pixel PXB may be disposed in each of the second pixel areas PA2.

In an embodiment, in the first pixel area PA1, the red sub-pixel PXR may be disposed adjacent to the blue sub-pixel PXB in the first direction DR1, and the green sub-pixel PXG may be disposed adjacent to the blue sub-pixel PXB in the first direction DR1. In addition, the red sub-pixel PXR and the green sub-pixel PXG may overlap each other in the second direction DR2 in a plan view. That is, the blue sub-pixel PXB may be positioned to the left of each of the red sub-pixel PXR and the green sub-pixel PXG.

Likewise, in an embodiment, in the second pixel area PA2, the red sub-pixel PXR may be disposed adjacent to the blue sub-pixel PXB in the first direction DR1, and the green sub-pixel PXG may be disposed adjacent to the blue sub-pixel PXB in the first direction DR1. In addition, the red sub-pixel PXR and the green sub-pixel PXG may overlap each other in the second direction DR2 in a plan view. That is, the blue sub-pixel PXB may be positioned to the left of each of the red sub-pixel PXR and the green sub-pixel PXG.

However, the invention is not limited to this, and the red sub-pixel PXR, the green sub-pixel PXG, and the blue sub-pixel PXB in the first pixel area PA1 and the second pixel area PA2 may be arranged in various ways.

In an embodiment and as shown in FIGS. 3 and 4, the arrangement of the plurality of sub-pixels disposed in each of the first pixel areas PA1 may be the same as the arrangement of the plurality of sub-pixels disposed in each of the second pixel areas PA2. In another embodiment, the arrangement of the sub-pixels disposed in each of the first pixel areas PA1 may be different from the arrangement of the sub-pixels disposed in each of the second pixel areas PA2.

In an embodiment, the area of the blue sub-pixel PXB may be different from the area of the red sub-pixel PXR and the area of the green sub-pixel PXG, respectively. In an embodiment, the area of the blue sub-pixel PXB may be larger than the area of the red sub-pixel PXR and the area of the green sub-pixel PXG, respectively. However, embodiments of the invention are not limited to this, and each of the blue sub-pixel PXB, the red sub-pixel PXR, and the green sub-pixel PXG may have variously sized areas.

In an embodiment, the red sub-pixel PXR, the green sub-pixel PXG, and the blue sub-pixel PXB may have the same planar shape. For example, each of the red sub-pixel PXR, the green sub-pixel PXG, and the blue sub-pixel PXB may have a rectangular planar shape. However, the invention is not limited to this, and each of the red sub-pixel PXR, the green sub-pixel PXG, and the blue sub-pixel PXB may have various planar shapes (e.g., a diamond-shaped planar shape or the like).

In an embodiment, the transmission areas TA may be areas through which external light incident on the display device DA transmits. As the second display area DA2 includes the transmissive areas TA through which external light is transmitted, the functional module disposed under the substrate SUB corresponding to the second display area DA2 may detect or recognize an object or user positioned in front of the display device DD through the transmission areas TA.

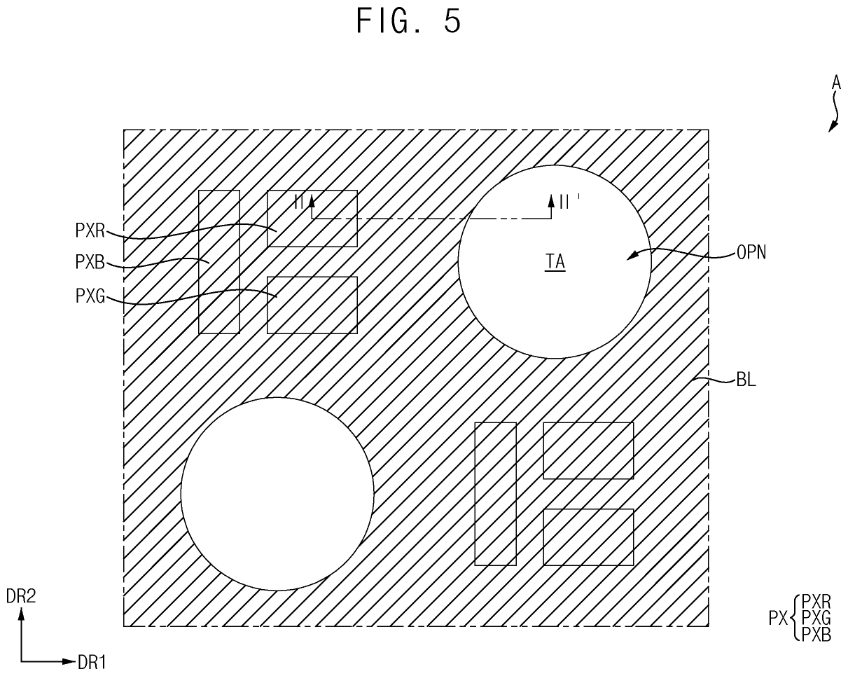

FIG. 5 is a plan view illustrating an example of area A of FIG. 4, according to an embodiment.

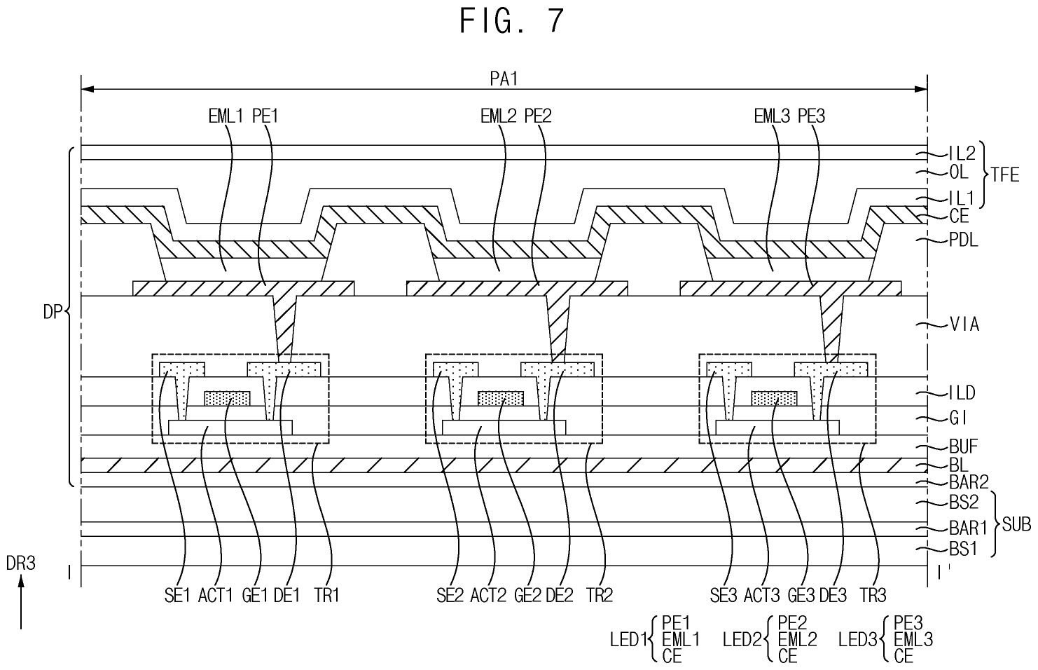

In an embodiment and referring to FIG. 5, a light blocking layer BL may be disposed in the second pixel areas PA2. The light blocking layer BL may also be disposed in the first pixel areas PA1 (see FIG. 7).

In an embodiment, an opening OPN overlapping each of the transmission areas TA may be defined in the light blocking layer BL. The light blocking layer BL may prevent light incident from the outside from flowing into the second pixel area PA2. In addition, the light blocking layer BL may prevent external light transmitted through the transmission areas TA from being diffracted around the transmission areas TA.

In an embodiment, the opening OPN of the light blocking layer BL may have various planar shapes. For example, the opening OPN may have a circular planar shape. However, the invention is not limited to this, and the opening OPN may have various planar shapes.

In an embodiment, the light blocking layer BL may include metal, metal oxide, and the like. For example, the light blocking layer BL may include a metal such as titanium (Ti), molybdenum (Mo), copper (Cu), and the like. These can be used alone or in combination with each other.

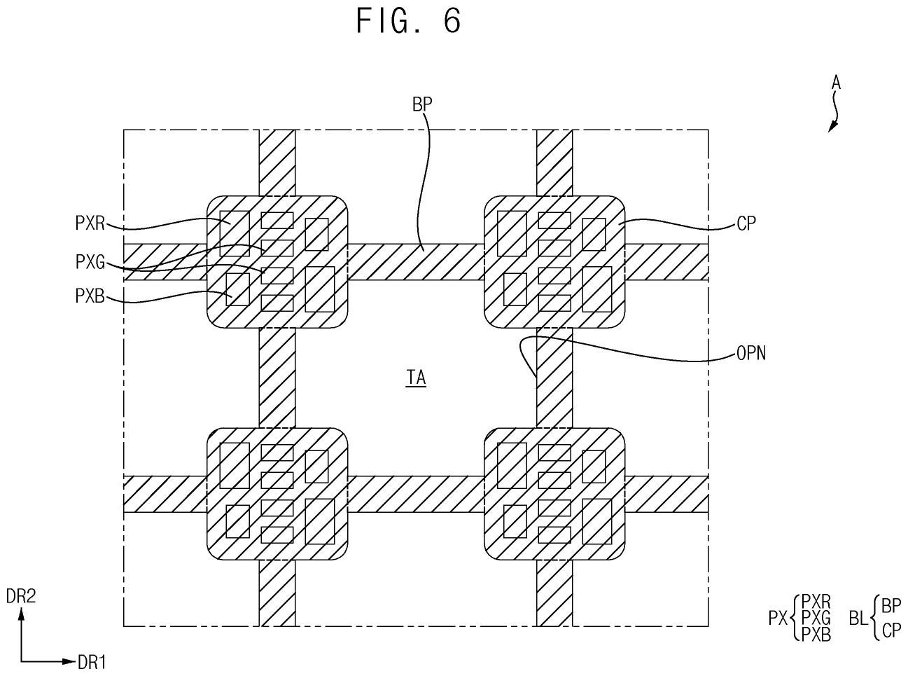

FIG. 6 is a plan view illustrating another example of area A of FIG. 4, according to an embodiment. Hereinafter, descriptions that overlap with those described with reference to FIG. 5 will be omitted or simplified.

In an embodiment and referring to FIG. 6, a light blocking layer BL may be disposed in the second pixel areas PA2. The light blocking layer BL may also be disposed in the first pixel areas PA1 (see FIG. 7).

In an embodiment, the light blocking layer BL may include a plurality of unit patterns CP and a plurality of bridge patterns BP connecting the unit patterns CP. Each of the unit patterns CP may be disposed in one second pixel area PA2. In this case, one pixel PX disposed in each of the second pixel areas PA2 may include two red sub-pixels PXR, four green sub-pixels PXG, and two blue sub-pixels PXB.

In an embodiment, an opening OPN overlapping each of the transmission areas TA may be defined in the light blocking layer BL. For example, the opening OPN may be defined by the unit patterns CP and the bridge patterns BP.

In an embodiment, the opening OPN of the light blocking layer BL may have various planar shapes. For example, the opening OPN may have a cross-shaped planar shape. In this case, the sizes of the top protrusion, bottom protrusion, left protrusion, and right protrusion of the opening OPN may be substantially the same.

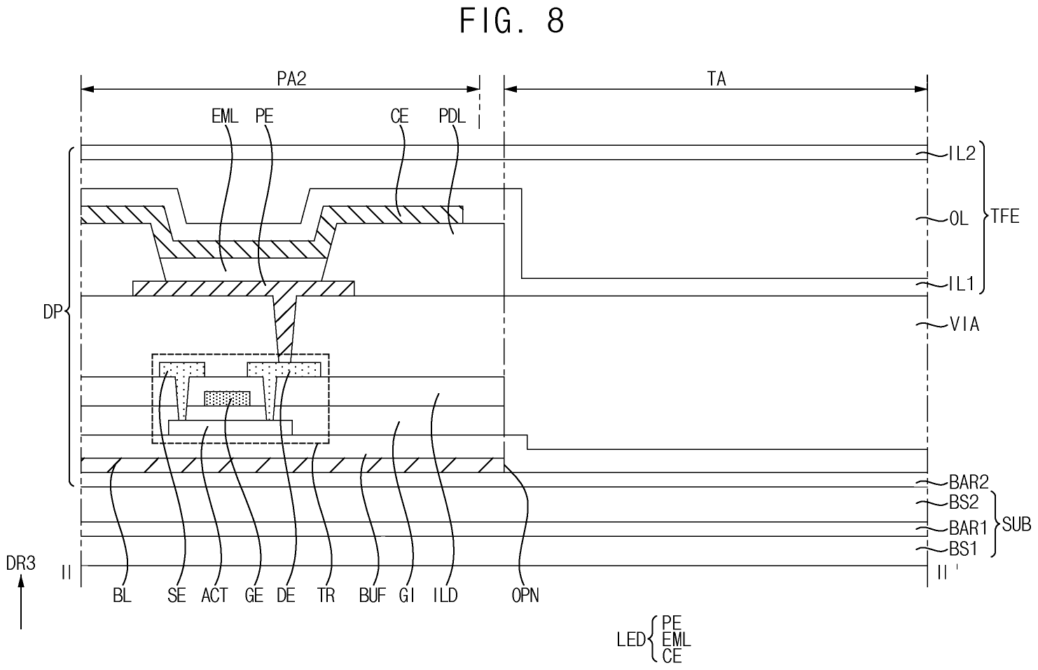

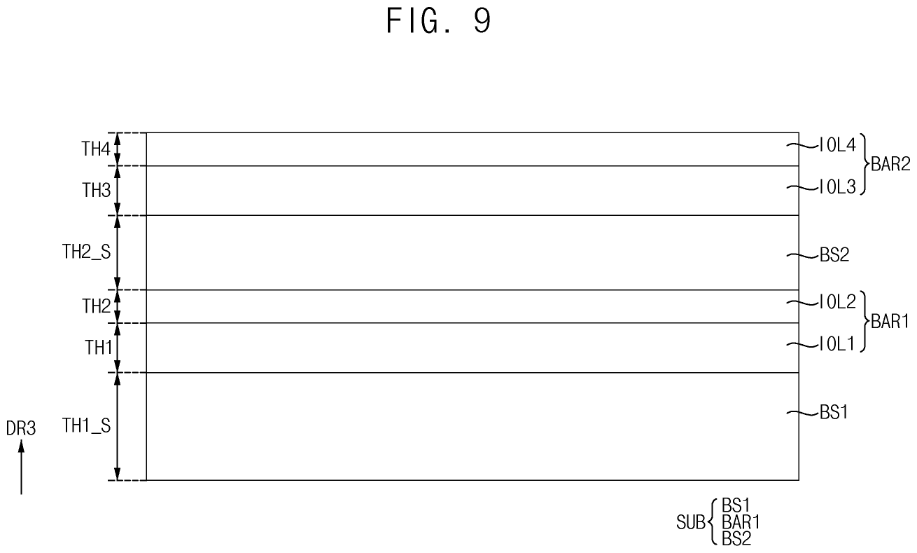

FIG. 7 is a cross-sectional view taken along line I-I′ of FIG. 3, according to an embodiment. FIG. 8 is a cross-sectional view taken along line II-II′ of FIG. 4, according to an embodiment. FIG. 9 is a cross-sectional view illustrating a substrate and a second barrier layer of FIGS. 7 and 8, according to an embodiment.

Referring to FIGS. 7, 8, and 9, the display device DD, according to an embodiment, may include the substrate SUB and the display portion DP. The display portion DP may include a second barrier layer BAR2, a buffer layer BUF, the light blocking layer BL, a transistor TR, first, second, and third transistors TR1, TR2, and TR3, respectively, a gate insulating layer GI, an interlayer insulating layer ILD, a via insulating layer VIA, a pixel defining layer PDL, a light emitting element LED, first, second, and third light emitting elements LED1, LED2, and LED3, respectively, and an encapsulation layer TFE.

In an embodiment, the transistor TR may include an active pattern ACT, a gate electrode GE, a source electrode SE, and a drain electrode DE.

In an embodiment, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

In an embodiment, the light emitting element LED may include a pixel electrode PE, a light emitting layer EML, and a common electrode CE. In addition, the first light emitting element LED1 may include a first pixel electrode PE1, a first light emitting layer EML1, and the common electrode CE, the second light emitting element LED2 may include a second pixel electrode PE2, a second light emitting layer EML2, and the common electrode CE, and the third light-emitting element LED3 may include a third pixel electrode PE3, a third light emitting layer EML3, and a common electrode CE.

In an embodiment and as described above, the display device DD may include the first display area DA1 and the second display area DA2. As the display device DD includes the first display area DA1 and the second display area DA2, components included in the display device DD (e.g., the substrate SUB, and the like) may also include the first display area DA1 and the second display area DA2.

In an embodiment, the substrate SUB may include a transparent material or an opaque material. The substrate SUB may be made of a transparent resin substrate. Examples of the transparent resin substrate may include a polyimide substrate. In another embodiment, the substrate may include a quartz substrate, a synthetic quartz substrate, a calcium fluoride substrate, a fluorine-doped quartz substrate, a soda-lime glass substrate, a non-alkali glass substrate, and the like. These can be used alone or in combination with each other.

In an embodiment, the substrate SUB may have a multilayer structure. In an embodiment, the substrate SUB may include a first base layer BS1, a first barrier layer BAR1, and a second base layer BS2 disposed to be stacked sequentially.

In an embodiment, each of the first base layer BS1 and the second base layer BS2 may include a polymer film or an inorganic material. For example, each of the first base layer BS1 and the second base layer BS2 may include a polymer film such as polyethylene terephthalate, polyethylene naphthalate, polyether ketone, polycarbonate, polyarylate, polyether sulfone, polyimide, and the like. These can be used alone or in combination with each other.

In an embodiment, each of the first base layer BS1 and the second base layer BS2 may include polyimide. In another embodiment, each of the first base layer BS1 and the second base layer BS2 may include silicon nitride (SiNₓ).

In an embodiment, each of the first base layer BS1 and the second base layer BS2 may have a relatively high refractive index with respect to the visible light wavelength. For example, the refractive index of each of the first base layer BS1 and the second base layer BS2 may be about 1.81. However, the invention is not limited thereto.

In an embodiment, a thickness TH1_S of the first base layer BS1 and a thickness TH2_S of the second base layer BS2 may each be about 1 μm. When each of the thickness TH1_S of the first base layer BS1 and the thickness TH2_S of the second base layer BS2 is less than about 1 μm, moisture permeability and interference with surrounding thin films may occur.

In an embodiment, the first barrier layer BAR1 can prevent penetration of moisture, and the like. The first barrier layer BAR1 may include an inorganic material. In an embodiment, the first barrier layer BAR1 may include a first inorganic layer IOL1 and a second inorganic layer IOL2 disposed on the first inorganic layer IOL1.

In an embodiment, the first inorganic layer IOL1 may include silicon oxynitride (SiON), and the second inorganic layer IOL2 may include silicon oxide (SiOₓ).

In an embodiment, with respect to the visible light wavelength, the first inorganic layer IOL1 may have a relatively medium refractive index, and the second inorganic layer IOL2 may have a relatively small refractive index. In an embodiment, the refractive index of the first base layer BS1 may be greater than the refractive index of the first inorganic layer IOL1, and the refractive index of the first inorganic layer IOL1 may be greater than the refractive index of the second inorganic layer IOL2. For example, the refractive index of the first inorganic layer IOL1 may be about 1.7, and the refractive index of the second inorganic layer IOL2 may be about 1.48. However, the invention is not limited thereto.

In an embodiment, the second barrier layer BAR2 may be disposed on the substrate SUB. The second barrier layer BAR2 can prevent penetration of unnecessary components such as impurities or moisture. The second barrier layer BAR2 may include an inorganic material. In an embodiment, the second barrier layer BAR2 may include a third inorganic layer IOL3 and a fourth inorganic layer IOL4 disposed on the third inorganic layer IOL3.

In an embodiment, the third inorganic layer IOL3 may include silicon oxynitride, and the fourth inorganic layer IOL4 may include silicon oxide.

In an embodiment, with respect to the visible light wavelength, the third inorganic layer IOL3 may have a relatively medium refractive index, and the fourth inorganic layer IOL4 may have a relatively small refractive index. In an embodiment, the refractive index of the second base layer BS2 may be greater than the refractive index of the third inorganic layer IOL3, and the refractive index of the third inorganic layer IOL3 may be greater than the refractive index of the fourth inorganic layer IOL4. For example, the refractive index of the third inorganic layer IOL3 may be about 1.7, and the refractive index of the fourth inorganic layer IOL4 may be about 1.48. However, the invention is not limited thereto.

In an embodiment, the first inorganic layer IOL1 may have a first thickness TH1, and the second inorganic layer IOL2 may have a second thickness TH2 which may be thinner than the first thickness TH1. In addition, the third inorganic layer IOL3 may have a third thickness TH3, and the fourth inorganic layer IOL4 may have a fourth thickness TH4 which may be thinner than the third thickness TH3.

In an embodiment, each of the first and third thicknesses TH1 and TH3, respectively, may satisfy Equation 1 below, and each of the second and fourth thicknesses TH2 and TH4, respectively, may satisfy Equation 2 below:

$$T 1 = ( λ 1 xm {/}_{2} ) / {n}_{1} , \qquad [ Equation 1 ]$$

$$T 2 = ( λ 2 xm {/}_{2} ) / {n}_{2} , \qquad [ Equation 2 ]$$

where in Equation 1, T1 is the thickness (Å) of any one of the first and third thicknesses, λ1 is a first wavelength within a visible light wavelength range, and n1 is a refractive index of any one of the first and third inorganic layers, and in Equation 2, T2 is the thickness (Å) of any one of the second and fourth thicknesses, λ2 is a second wavelength within a visible light wavelength range, and n2 is a refractive index of any one of the second and fourth inorganic layers, and wherein, m is a natural number.

In an embodiment, the first wavelength may be a wavelength of green light, and the second wavelength may be a wavelength of blue light. For example, the first wavelength may range from about 495 nm to about 605 nm, and the second wavelength may range from about 405 nm to about 495 nm.

In an embodiment, m may be any one of 1, 2, 3, 4, 5, and 6. In addition, the refractive index of each of the first and third inorganic layers IOL1 and IOL3, respectively, may be about 1.7, and the refractive index of each of the second and fourth inorganic layers IOL2 and IOL4, respectively, may be about 1.48.

In an embodiment, each of the first, second, third, and fourth thicknesses TH1, TH2, TH3, and TH4, respectively, may range from about 1000 Å to about 10000 Å. When each of the first, second, third, and fourth thicknesses TH1, TH2, TH3, and TH4, respectively, is less than 1000 Å, moisture permeation may occur. When each of the first, second, third, and fourth thicknesses TH1, TH2, TH3, and TH4, respectively, exceeds 10000 Å, stress or lifting may occur.

In an embodiment, the first thickness TH1 may be substantially the same as the third thickness TH3, and the second thickness TH2 may be substantially the same as the fourth thickness TH4. That is, the thickness of the first barrier layer BAR1 may be substantially the same as the thickness of the second barrier layer BAR2.

For example, in an embodiment, when m is 2, each of the first and third thicknesses TH1 and TH3, respectively, is determined by dividing the first wavelength of green light by the refractive index of each of the first and third inorganic layers IOL1 and IOL3, respectively, and each of the second and fourth thicknesses TH2 and TH4, respectively, may be determined by dividing the second wavelength of blue light by the refractive index of each of the second and fourth inorganic layers IOL2 and IOL4, respectively.

In an embodiment, when m is 2, each of the first and third thicknesses TH1 and TH3, respectively, may range from about 2900 Å to about 3600 Å, and each of the second and fourth thicknesses TH2 and TH4, respectively, may range from about 2700 Å to about 3400 Å.

In an embodiment, as each of the first and third thicknesses TH1 and TH3, respectively, satisfies Equation 1 above, and each of the second and fourth thicknesses TH2 and TH4, respectively, satisfies Equation 2, the average transmittance of the transmission area TA for blue light may relatively increase, and the average transmittance of the transmission area TA for green light may relatively decrease (or increase). In this case, the average transmittance of the transmission area TA for blue light divided by the average transmittance of the transmission area TA for green light may be relatively increased. Accordingly, the yellowish color of the image displayed through a functional module (e.g., the functional module FM of FIG. 2) can be minimized or reduced.

In an embodiment, the light blocking layer BL may be disposed on the second barrier layer BAR2. The light blocking layer BL may overlap the first display area DA1 and the second display area DA2. Specifically, the light blocking layer BL may overlap the entire first display area DA1 and the second pixel area PA2 of the second display area DA2.

In an embodiment and as described above, the opening OPN that overlaps the transmission area TA may be defined in the light blocking layer BL. That is, the transmission area TA may be defined by the opening OPN of the light blocking layer BL.

In an embodiment, the buffer layer BUF may be disposed on the light blocking layer BL. The buffer layer BUF can prevent metal atoms or impurities from diffusing from the substrate SUB to the transistors TR, TR1, TR2, and TR3. In addition, the buffer layer BUF can improve the flatness of the surface of the substrate SUB when the surface of the substrate SUB is not uniform. For example, the buffer layer BUF may include an inorganic material such as silicon oxide (SiOₓ), silicon nitride (SiNₓ), silicon oxynitride (SiOₓN_{y}), and the like. These can be used alone or in combination with each other. In an embodiment, the buffer layer BUF may include silicon nitride.

In an embodiment, the buffer layer BUF may have a relatively high refractive index with respect to the visible light wavelength. In an embodiment, the refractive index of the buffer layer BUF may be greater than the refractive index of each of the first, second, third, and fourth inorganic layers IOL1, IOL2, IOL3, and IOL4, respectively. For example, the refractive index of the buffer layer BUF may be about 1.89. However, the invention is not limited thereto.

In an embodiment, the first, second, and third active patterns ACT1, ACT2, and ACT3, respectively, may be disposed in the first pixel area PA1 on the buffer layer BUF. Each of the first, second, and third active patterns ACT1, ACT2, and ACT3, respectively, may include a source region, a drain region, and a channel region located between the source region and the drain region.

In an embodiment, each of the first, second, and third active patterns ACT1, ACT2, and ACT3, respectively, may include a metal oxide semiconductor (e.g., indium gallium zinc oxide (IGZO), and the like), an inorganic semiconductor (e.g., amorphous silicon, poly silicon, and the like), or an organic semiconductor.

In an embodiment, the active pattern ACT may be disposed in the second pixel area PA2 on the buffer layer BUF. The active pattern ACT may be formed through the same process as the first, second, and third active patterns ACT1, ACT2, and ACT3, respectively, and may include the same material as the first, second, and third active patterns ACT1, ACT2, and ACT3, respectively. In addition, the active pattern ACT may include a source region, a drain region, and a channel region located between the source region and the drain region.

In an embodiment, the gate insulating layer GI may be disposed on the buffer layer BUF. The gate insulating layer GI may sufficiently cover the active patterns ACT, ACT1, ACT2, and ACT3 and may have a substantially flat upper surface without creating steps around the active patterns ACT, ACT1, ACT2, and ACT3. In another embodiment, the gate insulating layer GI may cover the active patterns ACT, ACT1, ACT2, and ACT3 and may be disposed along the profile of each of the active patterns ACT, ACT1, ACT2, and ACT3 with a uniform thickness. For example, the gate insulating layer GI may include an inorganic material such as silicon oxide, silicon nitride, silicon oxynitride, and the like. These can be used alone or in combination with each other.

In an embodiment, the gate insulating layer GI may be disposed only in the first pixel area PA1 and the second pixel area PA2 and not in the transmission area TA. However, the invention is not limited thereto.

In an embodiment, the first, second, and third gate electrodes GE1, GE2, and GE3, respectively, may be disposed in the first pixel area PA1 on the gate insulating layer GI. The first, second, and third gate electrodes GE1, GE2, and GE3, respectively, may overlap the channel regions of the first, second, and third active patterns ACT1, ACT2, and ACT3, respectively. Each of the first, second, and third gate electrodes GE1, GE2, and GE3, respectively, may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide and indium zinc oxide. In addition, examples of the metal nitride may include aluminum nitride (AlNₓ), tungsten nitride (WNₓ), chromium nitride (CrNₓ), and the like. These can be used alone or in combination with each other.

In an embodiment, the gate electrode GE may be disposed in the second pixel area PA2 on the gate insulating layer GI. The gate electrode GE may be formed through the same process as the first, second, and third gate electrodes GE1, GE2, and GE3, respectively, and may include the same material as the first, second, and third gate electrodes GE1, GE2, and GE3, respectively. In addition, the gate electrode GE may overlap the channel area of the active pattern ACT.

In an embodiment, the interlayer insulating layer ILD may be disposed on the gate insulating layer GI. The interlayer insulating layer ILD may sufficiently cover the gate electrodes GE, GE1, GE2, and GE3 and may have a substantially flat upper surface without creating steps around the gate electrodes GE, GE1, GE2, and GE3. In another embodiment, the interlayer insulating layer ILD may cover the gate electrodes GE, GE1, GE2, and GE3 and may be disposed along the profile of each of the gate electrodes GE, GE1, GE2, and GE3 with a uniform thickness. For example, the interlayer dielectric layer ILD may include an inorganic material such as silicon oxide, silicon nitride, silicon oxynitride, and the like. These can be used alone or in combination with each other.

In an embodiment, the interlayer insulating layer ILD may be disposed only in the first pixel area PA1 and the second pixel area PA2, and might not be disposed in the transmission area TA. However, the invention is not limited thereto.

In an embodiment, the first, second, and third source electrodes SE1, SE2, and SE3, respectively, and the first, second, and third drain electrodes DE1, DE2, and DE3, respectively, may be disposed in the first pixel area PA1 on the interlayer insulating layer ILD. Each of the first, second, and third source electrodes SE1, SE2, and SE3, respectively, may be connected to the source region of the first, second, and third active patterns ACT1, ACT2, and ACT3, respectively, through a contact hole penetrating the gate insulating layer GI and the interlayer insulating layer ILD. In addition, each of the first, second, and third drain electrodes DE1, DE2, and DE3, respectively, may be connected to the drain region of the first, second, and third active patterns ACT1, ACT2, and ACT3, respectively, through a contact hole penetrating the gate insulating layer GI and the interlayer insulating layer ILD.

For example, in an embodiment, each of the first, second, and third source electrodes SE1, SE2, and SE3, respectively, and the first, second, and third drain electrodes DE1, DE2, and DE3, respectively, may include metal, alloy, metal nitride, conductive metal oxide, transparent conductive material, and the like. These can be used alone or in combination with each other.

In an embodiment, the source electrode SE and the drain electrode DE may be disposed in the second pixel area PA2 on the interlayer insulating layer ILD. The source electrode SE may be connected to the source region of the active pattern ACT through a contact hole penetrating the gate insulating layer GI and the interlayer insulating layer ILD. The drain electrode DE may be connected to the drain region of the active pattern ACT through a contact hole penetrating the gate insulating layer GI and the interlayer insulating layer ILD.

In an embodiment, the source electrode SE and the drain electrode DE may be formed through the same process as the first, second, and third source electrodes SE1, SE2, and SE3, respectively, and the first, second, and third drain electrodes DE1, DE2, and DE3, respectively. The source electrode SE and the drain electrode DE may include the same material as the first, second, and third source electrodes SE1, SE2, and SE3, respectively, and the first, second, and third drain electrodes DE1, DE2, and DE3, respectively.

In an embodiment, the via insulating layer VIA may be disposed on the interlayer insulating layer ILD. The via insulating layer VIA may sufficiently cover the source electrodes SE, SE1, SE2, and SE3 and the drain electrodes DE, DE1, DE2, and DE3. The via insulating layer VIA may include an organic material. For example, the via insulating layer VIA may include an organic material such as phenolic resin, polyacrylates resin, polyimides resin, polyamides resin, siloxane resin, epoxy resin, and the like. These can be used alone or in combination with each other.

In an embodiment, the via insulating layer VIA may be disposed in the first pixel area PA1, the second pixel area PA2, and the transmission area TA. However, the invention is not limited thereto.

In an embodiment, the first, second and third pixel electrodes PE1, PE2, and PE3, respectively, may be disposed in the first pixel area PA1 on the via insulating layer VIA. Each of the first, second and third pixel electrodes PE1, PE2, and PE3, respectively, may be connected to the first, second, and third drain electrodes DE1, DE2, and DE3, respectively, through a contact hole penetrating the via insulating layer VIA. For example, each of the first, second and third pixel electrodes PE1, PE2, and PE3, respectively, may include metal, alloy, metal nitride, conductive metal oxide, transparent conductive material, and the like. These can be used alone or in combination with each other.

In an embodiment, the pixel electrode PE may be disposed in the second pixel area PA2 on the via insulating layer VIA. The pixel electrode PE may be formed through the same process as the first, second and third pixel electrodes PE1, PE2, and PE3, respectively, and may include the same material as the first, second and third pixel electrodes PE1, PE2, and PE3, respectively. The pixel electrode PE may be connected to the drain electrode DE through a contact hole penetrating the via insulating layer VIA.

In an embodiment, the pixel defining layer PDL may be disposed on the via insulating layer VIA. The pixel defining layer PDL may cover the edges of each of the pixel electrodes PE, PE1, PE2, and PE3. In addition, an opening that exposes a part of the upper surface of each of the pixel electrodes PE, PE1, PE2, and PE3 may be defined in the pixel defining layer PDL. For example, the pixel defining layer PDL may include an inorganic material and/or an organic material.

In an embodiment, the pixel defining layer PDL may include an organic material such as epoxy resin, siloxane resin, and the like. These can be used alone or in combination with each other. In another embodiment, the pixel defining layer PDL may include an inorganic material and/or an organic material containing a light blocking material such as black pigment, black dye, and the like.

In an embodiment, the pixel defining layer PDL may be disposed only in the first pixel area PA1 and the second pixel area PA2 and might not disposed in the transmission area TA.

In an embodiment, the first, second, and third light emitting layers EML1, EML2, and EML3, respectively, may be disposed on the first, second and third pixel electrodes PE1, PE2, and PE3, respectively, respectively. Each of the first, second and third light emitting layers EML1, EML2, and EML3, respectively, may include an organic material that emits light of a preset color. For example, the first light emitting layer EML1 may include an organic material that emits red light, the second light emitting layer EML2 may include an organic material that emits green light, and the third light emitting layer EML3 may include an organic material that emits blue light.

In an embodiment, the light emitting layer EML may be disposed on the pixel electrode PE. For example, the light emitting layer EML may include an organic material that emits red light.

In an embodiment, the encapsulation layer TFE may be disposed on the common electrode CE. The encapsulation layer TFE can prevent impurities, moisture, and the like from penetrating into the light emitting elements LED, LED1, LED2, and LED3 from the outside. The encapsulation layer TFE may include at least one inorganic layer and at least one organic layer. In an embodiment, the encapsulation layer TFE may include a first inorganic encapsulation layer IL1, an organic encapsulation layer OL, and a second inorganic encapsulation layer IL2.

In an embodiment, the first inorganic encapsulation layer IL1 may be disposed on the common electrode CE. The first inorganic encapsulation layer ILI may overlap the first display area DA1 and the second display area DA2. For example, the first inorganic encapsulation layer IL1 may include an inorganic material such as silicon oxide, silicon nitride, silicon oxynitride, and the like. These can be used alone or in combination with each other.

In an embodiment, the organic encapsulation layer OL may be disposed on the first inorganic encapsulation layer IL1. The organic encapsulation layer OL may overlap the first display area DA1 and the second display area DA2. For example, the organic encapsulation layer OL may include an organic material such as polyethylene terephthalate, polyethylene naphthalate, polycarbonate, polyimide, polyethylene sulfonate, polyoxymethylene, polyarylate, hexamethyldisiloxane, acrylic resin, and the like. These can be used alone or in combination with each other.

In an embodiment, the second inorganic encapsulation layer IL2 may be disposed on the organic encapsulation layer OL. The second inorganic encapsulation layer IL2 may overlap the first display area DA1 and the second display area DA2. For example, the second inorganic encapsulation layer IL2 may include an inorganic material such as silicon oxide, silicon nitride, silicon oxynitride, and the like. These can be used alone or in combination with each other.

Hereinafter, the effects of the invention according to comparative embodiments and other embodiments will be described.

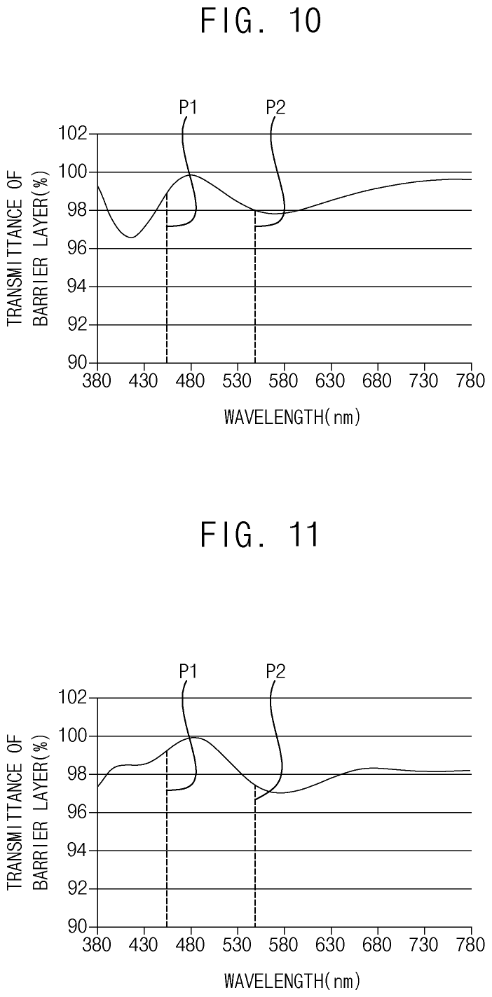

FIG. 10 is a graph illustrating a transmittance of the barrier layer for the wavelength of visible light in a comparative embodiment. FIG. 11 is a graph illustrating a transmittance of the barrier layer for the wavelength of visible light, according to an embodiment.

In a comparative embodiment and an embodiment, the transmittance of a barrier layer to light having a first wavelength P1 and the transmittance of the barrier layer to light having a second wavelength P2 were measured. The first wavelength P1 was about 450 nm, and the second wavelength P2 was about 550 nm.

In a comparative embodiment, the barrier layer included a first barrier layer and a second barrier layer, each of the first barrier layer and the second barrier layer included a first inorganic layer formed of silicon oxynitride and having a refractive index of about 1.7, and a second inorganic layer formed of silicon oxide and having a refractive index of about 1.48. The thickness of the first inorganic layer of the first barrier layer was about 1000 Å, and the thickness of the second inorganic layer of the first barrier layer was about 5000 Å. The thickness of the first inorganic layer of the second barrier layer was about 1000 Å, and the thickness of the second inorganic layer of the second barrier layer was about 5700 Å.

In an embodiment, the barrier layer included a first barrier layer and a second barrier layer, and each of the first barrier layer and the second barrier layer included a first inorganic layer formed of silicon oxynitride and a second inorganic layer formed of silicon oxide.

In an embodiment, the thickness of the first inorganic layer of each of the first and second barrier layers is calculated via Equation 1 hereinabove, and the thickness of the second inorganic layer of each of the first and second barrier layers is calculated via Equation 2 hereinabove.

The thickness of the first inorganic layer that satisfies the embodiment is calculated by substituting the first wavelength (λ1) as being about 550 nm, the refractive index (n₁) of the first inorganic layer as being about 1.7, and m as being 2 in Equation 1 hereinabove. In addition, the thickness of the second inorganic layer that satisfies the embodiment is calculated by substituting the second wavelength (λ2) as being about 450 nm, the refractive index (n₂) of the second inorganic layer as being about 1.48, and m as being 2 in Equation 2 herein above.

As a result, in an embodiment and referring to FIG. 10, in the barrier layer satisfying the comparative embodiment, it can be confirmed that the transmittance of the barrier layer to light having the first wavelength P1 (i.e., blue light) is about 98% and the transmittance of the barrier layer to light having a wavelength P2 (i.e., green light) is about 98%. On the other hand, referring to FIG. 11, in the barrier layer satisfying the embodiment, it can be confirmed that the transmittance of the barrier layer to blue light having a first wavelength P1 is about 99%, and the transmittance of the barrier layer for green light having the second wavelength P2 is about 97%.

Through this, it can be confirmed that in the above embodiment, the transmittance of the barrier layer to blue light increases and the transmittance of the barrier layer to green light decreases compared to the comparative embodiment.

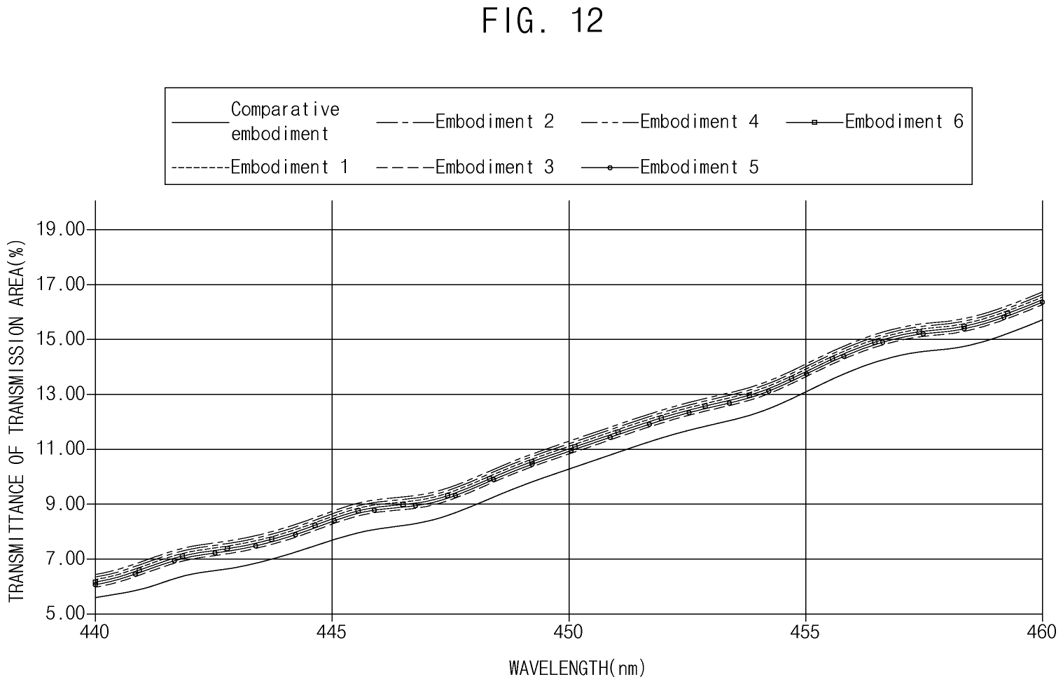

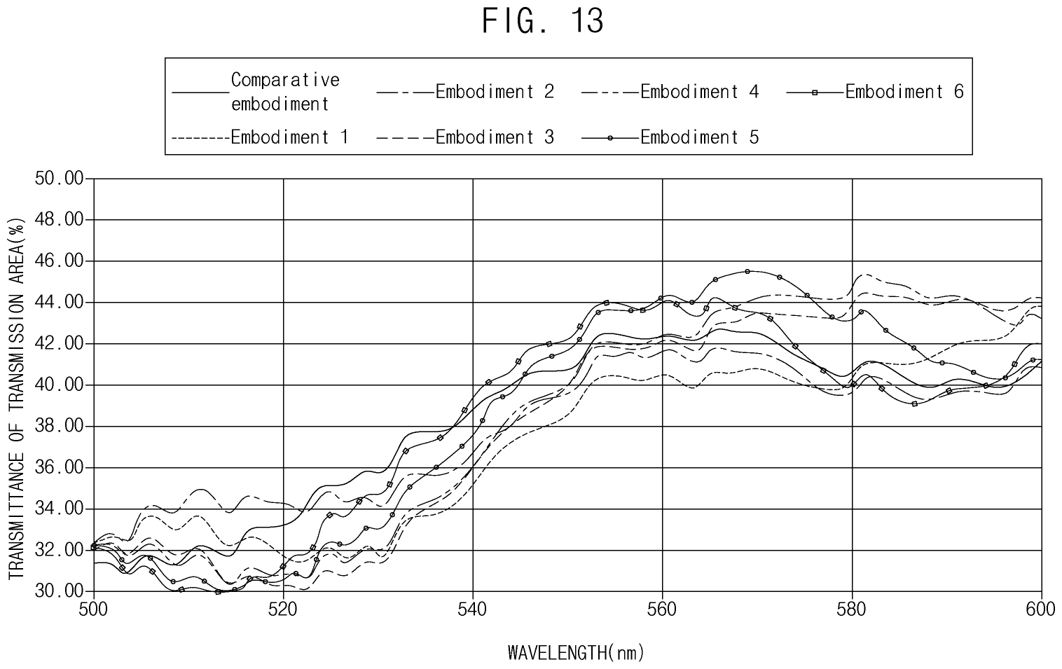

FIG. 12 is a view illustrating a transmittance of a transmission area for a first wavelength included in a visible light wavelength range in comparative embodiments and embodiments. FIG. 13 is a view illustrating a transmittance of a transmission area for a first wavelength included in a visible light wavelength range in comparative embodiments and embodiments. For example, the first wavelength of FIG. 12 is a wavelength of blue light, and the second wavelength of FIG. 13 is a wavelength of green light.

In comparative embodiments and embodiments, the average transmittance of the transmission area for blue light having the first wavelength and the average transmittance of the transmission area for green light having the second wavelength were measured. The first wavelength ranged from about 440 nm to about 460 nm, and the second wavelength ranged from about 540 nm to about 560 nm.

In comparative embodiments, the material and refractive index of each of a first base layer, a first barrier layer, a second base layer, a second barrier layer, and a buffer layer satisfied Table 1 below.

In addition, in embodiments 1, 2, 3, 4, 5, and 6, the material and refractive index of each of a first base layer, a first barrier layer, a second base layer, a second barrier layer, and a buffer layer satisfied Table 1 below. In an embodiment, the first barrier layer includes a first inorganic layer and a second inorganic layer, and the second barrier layer included a third inorganic layer and a fourth inorganic layer.

TABLE 1

| | Material | Refractive index |
|---|---|---|
| Buffer layer | SiNx | 1.89 |
| Fourth inorganic layer | SiOx | 1.48 |
| Third inorganic layer | SiON | 1.7 |
| Second base layer | Polyimide (PI) | 1.81 |
| Second inorganic layer | SiOx | 1.48 |
| First inorganic layer | SiON | 1.7 |
| First base layer | Polyimide (PI) | 1.81 |

In addition, in comparative embodiments, the thicknesses of each of the first base layer, the first barrier layer, the second base layer, the second barrier layer, and the buffer layer satisfied Table 2 below. In addition, in embodiments 1, 2, 3, 4, 5, and 6, the thickness of each of the first base layer, the first barrier layer, the second base layer, the second barrier layer, and the buffer layer satisfied Table 2 below. In Table 2 below, the units of thickness are angstroms (Å) and the thicknesses are approximate values.

In embodiments 1, 2, 3, 4, 5, and 6, the thickness of each of the first and third inorganic layers is calculated via Equation 1 hereinabove, and the thickness of each of the second and fourth inorganic layers is calculated via Equation 2 hereinabove.

The thickness of each of the first and third inorganic layers that satisfies the embodiment 1 is calculated by substituting the first wavelength (λ1) as being about 550 nm, the refractive index (n₁) of each of the first and third inorganic layers as being about 1.7, and m as being 2 in Equation 1 hereinabove. In addition, the thickness of each of the second and fourth inorganic layers that satisfies the embodiment is calculated by substituting the second wavelength (λ2) as being about 450 nm, the refractive index (n₂) each of the second and fourth inorganic layers as being about 1.48, and m as being 2 in Equation 2 hereinabove.

The thickness of each of the first and third inorganic layers satisfying embodiment 2 was calculated by substituting the remaining values in the same manner as in embodiment 1, except that m is 1 in Equation 1. In addition, the thickness of each of the second and fourth inorganic layers satisfying embodiment 2 was calculated by substituting the remaining values in the same manner as in embodiment 1, except that m is 1 in Equation 2.

The thickness of each of the first and third inorganic layers satisfying embodiment 3 was calculated by substituting the remaining values in the same manner as in embodiment 1, except that m is 3 in Equation 1. In addition, the thickness of each of the second and fourth inorganic layers satisfying embodiment 3 was calculated by substituting the remaining values in the same manner as in embodiment 1, except that m is 3 in Equation 2.

The thickness of each of the first and third inorganic layers satisfying embodiment 4 was calculated by substituting the remaining values in the same manner as in embodiment 1, except that m is 4 in Equation 1. In addition, the thickness of each of the second and fourth inorganic layers satisfying embodiment 4 was calculated by substituting the remaining values in the same manner as in embodiment 1, except that m is 4 in Equation 2.

The thickness of each of the first and third inorganic layers satisfying embodiment 5 was calculated by substituting the remaining values in the same manner as in embodiment 1, except that m is 5 in Equation 1. In addition, the thickness of each of the second and fourth inorganic layers satisfying embodiment 5 was calculated by substituting the remaining values in the same manner as in embodiment 1, except that m is 5 in Equation 2.

The thickness of each of the first and third inorganic layers satisfying embodiment 6 was calculated by substituting the remaining values in the same manner as in embodiment 1, except that m is 6 in Equation 1. In addition, the thickness of each of the second and fourth inorganic layers satisfying embodiment 6 was calculated by substituting the remaining values in the same manner as in embodiment 1, except that m is 6 in Equation 2.

TABLE 2

| | Comparative | | | | | | |
|---|---|---|---|---|---|---|---|
| | embodiment | Embodiment 1 | Embodiment 2 | Embodiment 3 | Embodiment 4 | Embodiment 5 | Embodiment 6 |
| Buffer | 350 | 350 | 350 | 350 | 350 | 350 | 350 |
| layer | | | | | | | |
| Fourth | 5700 | 3040 | 1520 | 4560 | 6080 | 7060 | 9120 |
| inorganic | | | | | | | |
| layer | | | | | | | |
| Third | 1000 | 3240 | 1620 | 4850 | 6470 | 8090 | 9710 |
| inorganic | | | | | | | |
| layer | | | | | | | |
| Second | 56000 | 56000 | 56000 | 56000 | 56000 | 56000 | 56000 |
| base | | | | | | | |
| layer | | | | | | | |
| Second | 500 | 3040 | 1520 | 4560 | 6080 | 7060 | 9120 |
| inorganic | | | | | | | |
| layer | | | | | | | |
| First | 1000 | 3240 | 1620 | 4850 | 6470 | 8090 | 9710 |
| inorganic | | | | | | | |
| layer | | | | | | | |
| First base | 100000 | 100000 | 100000 | 100000 | 100000 | 100000 | 100000 |
| layer | | | | | | | |

As a result, referring to Table 3 and FIGS. 12 and 13, it can be confirmed that the average transmittance of the transmission area for blue light according to embodiments 1, 2, 3, 4, 5, and 6 is greater than the average transmittance of the transmission area for blue light according to the comparative embodiment, and the average transmittance of the transmission area for green light according to embodiments 1, 2, 3, 4, 5, and 6 is smaller or greater than the average transmittance of the transmission area for blue light according to the comparative embodiment.

TABLE 3

| | Average transmittance | Average transmittance | |
|---|---|---|---|
| | of the transmission | of the transmission area | |
| | area for blue light (A) | for green light (B) | A/B |
| Comparative | 10.7% | 40.5% | 0.26 |
| embodiment | | | |
| Embodiment 1 | 11.4% | 37.8% | 0.30 |
| Embodiment 2 | 11.5% | 39.1% | 0.29 |
| Embodiment 3 | 11.2% | 39.1% | 0.29 |
| Embodiment 4 | 11.4% | 39.3% | 0.29 |
| Embodiment 5 | 11.4% | 41.0% | 0.28 |
| Embodiment 6 | 11.3% | 41.3% | 0.27 |

Through this, it can be confirmed that the average transmittance of the transmission area for blue light divided by the average transmittance of the transmission area for green light according to embodiments 1, 2, 3, 4, 5, and 6 is greater than the average transmittance of the transmission area for blue light divided by the average transmittance of the transmission area for green light according to the comparative embodiment.

The invention can be applied to various display devices. For example, the invention is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as disclosed in the specification and defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention. Moreover, the embodiments or parts of the embodiments may be combined in whole or in part without departing from the scope of the invention.

What is claimed is:

1. A display device comprising:
a first base layer including,
a first display area including a first pixel area, and a second display area at least partially surrounded by the first display area and including a transmission area and a second pixel area;
a first barrier layer disposed on the first base layer and including a first inorganic layer having a first thickness and a second inorganic layer having a second thickness, wherein the second thickness is thinner than the first thickness;
a second base layer disposed on the first barrier layer;
a second barrier layer disposed on the second base layer, and including a third inorganic layer having a third thickness and a fourth inorganic layer having a fourth thickness, wherein the fourth thickness is thinner than the third thickness; and
a plurality of pixels disposed on the second barrier layer to be located within the first pixel area and the second pixel area,
wherein each of the first thickness and the third thickness satisfies,
$$T 1 = ( {λ}_{1} xm / 2 ) / {n}_{1} , \qquad [ Equation 1 ]$$
and wherein each of the second thickness and the fourth thickness satisfies,
$$T 2 = ( {λ}_{2} xm / 2 ) / {n}_{2} , \qquad [ Equation 2 ]$$
wherein, in Equation 1, T1 is the thickness (Å) of any one of the first thickness and the third thickness, λ₁ is a first wavelength within a visible light wavelength range, and n₁ is a refractive index of any one of the first inorganic layer and the third inorganic layer, and wherein, in Equation 2, T2 is the thickness (Å) of any one of the second thickness and the fourth thickness, λ₂ is a second wavelength within a visible light wavelength range, and n₂ is a refractive index of any one of the second inorganic layer and the fourth inorganic layer, and wherein m is a natural number.

2. The display device of claim 1, wherein the first thickness and the third thickness are substantially equal, and the second thickness and the fourth thickness are substantially equal.

3. The display device of claim 1, wherein the first wavelength is a wavelength of green light and the second wavelength is a wavelength of blue light.

4. The display device of claim 1, wherein each of the first thickness, second thickness, third thickness, and fourth thickness range from about 1000 Å to about 10000 Å.

5. The display device of claim 1, wherein a refractive index of the first base layer is greater than a refractive index of the first inorganic layer, and the refractive index of the first inorganic layer is greater than a refractive index of the second inorganic layer.

6. The display device of claim 5, wherein a refractive index of the second base layer is greater than a refractive index of the third inorganic layer, and the refractive index of the third inorganic layer is greater than a refractive index of the fourth inorganic layer.

7. The display device of claim 1, wherein the first inorganic layer and the third inorganic layer includes silicon oxynitride, and the second inorganic layer and the fourth inorganic layer includes silicon oxide.

8. The display device of claim 1, further comprising;
a buffer layer disposed on the second base layer and including an inorganic material.

9. The display device of claim 8, wherein a refractive index of the buffer layer is greater than the refractive index of each of the first inorganic layer, the second inorganic layer, the third inorganic layer and the fourth inorganic layer.

10. The display device of claim 1, wherein each of the first base layer and the second base layer includes polyimide.

11. The display device of claim 1, wherein each of the first base layer and the second base layer includes silicon nitride.

12. The display device of claim 1, wherein a transmittance of the first display area is smaller than a transmittance of the second display area.

13. The display device of claim 12, further comprising;
a functional module disposed under the first base layer corresponding to the second display area.

14. The display device of claim 13, wherein the functional module includes at least one of a camera module, a face recognition sensor module, a pupil recognition sensor module, an acceleration sensor module, a proximity sensor module, an infrared senser module, and an illuminance sensor module.

15. A display device comprising:
a first base layer including a first display area including a first pixel area, and a second display area at least partially surrounded by the first display area and including a transmission area and a second pixel area;
a first barrier layer disposed on the first base layer and including a first inorganic layer having a first thickness and a second inorganic layer having a second thickness, wherein the second thickness is thinner than the first thickness;
a second base layer disposed on the first barrier layer;
a second barrier layer disposed on the second base layer and including a third inorganic layer having a third thickness and a fourth inorganic layer having a fourth thickness, wherein the fourth thickness is thinner than the third thickness; and
a plurality of pixels disposed on the second barrier layer to be located in the first pixel area and the second pixel area,
wherein the first thickness is determined by dividing a first wavelength of green light by a refractive index of the first inorganic layer, and the second thickness is determined by dividing a second wavelength of blue light by a refractive index of the second inorganic layer.

16. The display device of claim 15, wherein the first thickness ranges from about 2900 Å to about 3600 Å, and the second thickness ranges from about 2700 Å to about 3400 Å.

17. The display device of claim 15, wherein a refractive index of the first base layer is greater than a refractive index of the first inorganic layer, and the refractive index of the first inorganic layer is greater than a refractive index of the second inorganic layer.

18. The display device of claim 17, wherein a refractive index of the second base layer is greater than a refractive index of the third inorganic layer, and the refractive index of the third inorganic layer is greater than a refractive index of the fourth inorganic layer.

19. The display device of claim 15, wherein the first and third inorganic layers include silicon oxynitride, and the second and fourth inorganic layers include silicon oxide.

20. The display device of claim 15, further comprising;
a buffer layer disposed on the second base layer and including an inorganic material.

21. The display device of claim 20, wherein a refractive index of the buffer layer is greater than the refractive index of each of the first inorganic layer, the second inorganic layer, the third inorganic layer and the fourth inorganic layer.

22. The display device of claim 15, wherein each of the first base layer and the second base layer includes polyimide.

23. The display device of claim 15, wherein each of the first base layer and the second base layer includes silicon nitride.
